(19) United States
(12) Patent Application Publication
(10) Pub. No.: US 2026/0282953 A1
(43) Pub. Date: Sep. 17, 2026

(54) MULTICHIP MODULE INCLUDING FOLDED SUBSTRATE

(71) Applicant: QUALCOMM Incorporated, San Diego, CA (US)

(72) Inventors: Aniket PATIL, San Diego, CA (US); Zhijie WANG, San Diego, CA (US); Joan Rey Villarba BUOT, Escondido, CA (US)

(21) Appl. No.: 19/080,490

(22) Filed: Mar. 14, 2025

(51) Int. Cl. H01L 23/538; H01L 23/00; H01L 23/373; H01L 25/11; H10B 80/00

(52) U.S. Cl. CPC H10W 70/614; H10W 70/611; H10W 70/688; H10W 90/00; H10B 80/00; H10W 40/25; H10W 72/877; H10W 90/724; H10W 90/734

(57) ABSTRACT

A multichip module includes a folded substrate having a central region and a first flap and a second flap disposed at opposite sides of the central region, the first flap being folded to overlie at least a first portion of the central region of the folded substrate, the second flap being folded to overlie a second portion of the central region. A first integrated circuit package is electrically connected to a first set of one or more contacts disposed at an interior surface of the central region of the folded substrate. A second integrated circuit package is electrically connected to a second set of one or more contacts at an outer surface of the first flap. A third integrated circuit package is electrically connected to a third set of one or more contacts at an outer surface of the second flap.

### FIELD OF DISCLOSURE

The present disclosure generally relates to integrated circuit technology and, more particularly, to a multichip module including a folded substrate.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system-on-chip (SOC) devices, which may include multiple function blocks, with each function block designed to perform a specific function, such as, for example, a microprocessor function, a graphics processing unit (GPU) function, a communications function (e.g., WiFi, Bluetooth, and other communications), and the like.

In advanced electronic packaging, package miniaturization has become desirable due to the growing need for compact, high-performance devices in consumer electronics, automotive systems, and medical technologies. Modern applications, such as smartphones, wearables, and Internet of Things (IoT) devices, require increasingly smaller form factors while maintaining or enhancing functionality. The increasingly smaller form factors and enhanced functionality give rise to a need for high-density integration of the components in such applications to incorporate multiple features, such as processing, storage, and connectivity, within a single package or a reduced number of small modules that may be integrated into smaller packaging units.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose of presenting certain concepts relating to one or more aspects relating to the mechanisms disclosed herein in a simplified form to precede the detailed description presented below.

In an aspect, an electronic device includes a multichip module includes a folded substrate having a central region and at least a first flap and a second flap disposed at opposite sides of the central region, the first flap being folded at a first bend line to overlie at least a first portion of the central region of the folded substrate, the second flap being folded at a second bend line to overlie a second portion of the central region; a first integrated circuit package electrically connected to a first set of one or more contacts disposed at an interior surface of the central region of the folded substrate, an interior surface of the first flap overlying at least a portion of the first integrated circuit package, and an interior surface of the second flap overlying at least a further portion of the first integrated circuit package; a second integrated circuit package electrically connected to a second set of one or more contacts at an outer surface of the first flap; a third integrated circuit package electrically connected to a third set of one or more contacts at an outer surface of the second flap; and one or more metallizations formed in the folded substrate to electrically connect the first set of one or more contacts at the interior surface of the central region with the second set of one or more contacts at the outer surface of the first flap, the one or more metallizations further electrically connect the first set of one or more contacts at the interior surface of the central region with the third set of one or more contacts at the outer surface of the second flap.

In an aspect, a multichip module includes a folded substrate having a central region and at least a first flap and a second flap disposed at opposite sides of the central region, the first flap being folded at a first bend line to overlie at least a first portion of the central region of the folded substrate, the second flap being folded at a second bend line to overlie a second portion of the central region; a first integrated circuit package electrically connected to a first set of one or more contacts disposed at an interior surface of the central region of the folded substrate, an interior surface of the first flap overlying at least a portion of the first integrated circuit package, and an interior surface of the second flap overlying at least a further portion of the first integrated circuit package; a second integrated circuit package electrically connected to a second set of one or more contacts at an outer surface of the first flap; a third integrated circuit package electrically connected to a third set of one or more contacts at an outer surface of the second flap; and one or more metallizations formed in the folded substrate to electrically connect the first set of one or more contacts at the interior surface of the central region with the second set of one or more contacts at the outer surface of the first flap, the one or more metallizations further electrically connect the first set of one or more contacts at the interior surface of the central region with the third set of one or more contacts at the outer surface of the second flap.

In an aspect, an electronic device includes a multichip module including a folded substrate comprising a central region having a first set of one or more contacts at an inner surface of a first side portion of the central region and a second set of one or more contacts at an inner surface of a second side portion of the central region, at least a first flap adjacent to the first side portion of the central region and a second flap adjacent the second side portion of the central region, the first flap having a third set of one or more contacts at an inner surface of the first flap, and the second flap having a fourth set of one or more contacts at an inner surface of the second flap, the first flap being folded at a first bend line to place the third set of one or more contacts in electrical contact with the first set of one or more contacts, the second flap being folded at a second bend line to place the fourth set of one or more contacts in electrical contact with the second set of one or more contacts; a first integrated circuit package electrically connected to a fifth set of one or more contacts at an interior surface of the central region, the first integrated circuit package being disposed in an open region formed between edges of the first flap and the second flap; and a first set of one or more metallizations formed in the folded substrate to electrically connect two or more of the first set of one or more contacts, the second set of one or more contacts, the third set of one or more contacts, the fourth set of one or more contacts, and fifth set of one or more contacts with one another.

In an aspect, a multichip module includes a folded substrate comprising a central region having a first set of one or more contacts at an inner surface of a first side portion of the central region and a second set of one or more contacts at an inner surface of a second side portion of the central region, at least a first flap adjacent to the first side portion of the central region and a second flap adjacent the second side portion of the central region, the first flap having a third set of one or more contacts at an inner surface of the first flap, and the second flap having a fourth set of one or more contacts at an inner surface of the second flap, the first flap being folded at a first bend line to place the third set of one or more contacts in electrical contact with the first set of one or more contacts, the second flap being folded at a second bend line to place the fourth set of one or more contacts in electrical contact with the second set of one or more contacts; a first integrated circuit package electrically connected to a fifth set of one or more contacts at an interior surface of the central region, the first integrated circuit package being disposed in an open region formed between edges of the first flap and the second flap; and a first set of one or more metallizations formed in the folded substrate to electrically connect two or more of the first set of one or more contacts, the second set of one or more contacts, the third set of one or more contacts, the fourth set of one or more contacts, and fifth set of one or more contacts with one another.

In an aspect, a method of fabricating a multichip module includes forming a folded substrate having a central region and at least a first flap and a second flap disposed at opposite sides of the central region, the first flap being folded at a first bend line to overlie at least a first portion of the central region of the folded substrate, the second flap being folded at a second bend line to overlie a second portion of the central region; electrically connecting a first integrated circuit package electrically to a first set of one or more contacts disposed at an interior surface of the central region of the folded substrate, an interior surface of the first flap overlying at least a portion of the first integrated circuit package, and an interior surface of the second flap overlying at least a further portion of the first integrated circuit package; electrically connecting a second integrated circuit package to a second set of one or more contacts at an outer surface of the first flap; electrically connecting a third integrated circuit package to a third set of one or more contacts at an outer surface of the second flap; and forming one or more metallizations in the folded substrate to electrically connect the first set of one or more contacts at the interior surface of the central region with the second set of one or more contacts at the outer surface of the first flap, the one or more metallizations further electrically connect the first set of one or more contacts at the interior surface of the central region with the third set of one or more contacts at the outer surface of the second flap.

In an aspect, a method of fabricating a multichip module includes forming a folded substrate having a central region having a first set of one or more contacts at an inner surface of a first side portion of the central region and a second set of one or more contacts at an inner surface of a second side portion of the central region, at least a first flap adjacent to the first side portion of the central region and a second flap adjacent the second side portion of the central region, the first flap having a third set of one or more contacts at an inner surface of the first flap, and the second flap having a fourth set of one or more contacts at an inner surface of the second flap, the first flap being folded at a first bend line to place the third set of one or more contacts in electrical contact with the first set of one or more contacts, the second flap being folded at a second bend line to place the fourth set of one or more contacts in electrical contact with the second set of one or more contacts; electrically connecting a first integrated circuit package to a fifth set of one or more contacts at an interior surface of the central region, the first integrated circuit package being disposed in an open region formed between edges of the first flap and the second flap; and forming a first set of one or more metallizations in the folded substrate to electrically connect two or more of the first set of one or more contacts, the second set of one or more contacts, the third set of one or more contacts, the fourth set of one or more contacts, and fifth set of one or more contacts with one another.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, which are presented solely for illustration and not limitation of the disclosure.

FIG. 1 shows an example double data rate (DDR) memory module, according to aspects of the disclosure.

FIG. 2 shows an example DDR memory module, according to aspects of the disclosure.

FIG. 3 shows an example DDR memory module, according to aspects of the disclosure.

FIG. 4 is a plan view of an example foldable substrate that may be used in a multichip module, according to aspects of the disclosure.

FIG. 5 is a cross-sectional view of a multichip module, according to aspects of the disclosure.

FIG. 6 is a cross-sectional view of a multichip module, according to aspects of the disclosure.

FIG. 7 is a plan view of an example foldable substrate that may be used in a multichip module, according to aspects of the disclosure.

FIG. 8 is a cross-sectional view of a multichip module, according to aspects of the disclosure.

FIG. 9A through FIG. 9D illustrate example processing operations that may be used to fabricate a multichip module, according to aspects of the disclosure.

FIG. 10A and FIG. 10B illustrate example processing operations that may be performed in forming a first example architecture of a multichip module, according to aspects of the disclosure.

FIG. 11A through FIG. 11D illustrate example processing operations that may be performed in forming a second example architecture of a multichip module, according to aspects of the disclosure.

FIG. 12 illustrates another example of a multichip module, according to aspects of the disclosure.

FIG. 13A through FIG. 13G illustrate example processing operations that may be used to fabricate a multichip module, according to aspects of the disclosure.

FIG. 14 shows an example method of fabricating a multichip module, according to aspects of the disclosure.

FIG. 15 shows an example method of fabricating a multichip module, according to aspects of the disclosure.

FIG. 16 illustrates a profile view of a package that includes a surface mount substrate, an integrated device, and a multichip module, according to aspects of the disclosure.

FIG. 17 illustrates an example method for providing or fabricating a package that includes an integrated device comprising an electronic component mounted in a core, according to aspects of the disclosure.

FIG. 18 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC).

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various components and portions of operations can be taken from known, conventional techniques and then arranged in accordance with one or more exemplary embodiments. In such instances, internal details of the known, conventional components and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

As used herein, the term “contact” refers to any conductive element designed to establish an electrical connection, including: 1) pads, 2) pins, 3) bumps (e.g., in flip-chip technology), 4) contact points in connectors or sockets, or 5) any combination of such elements. As used herein, the term “metallization structure” refers to the patterned metallization layers, the metalized vias, and the contacts formed in a substrate that are configured to electrically connect the electrical components mounted on the substrate.

Certain aspects of the disclosure find applications in multichip modules incorporating dynamic random access memories (DRAMs), such as those including double data rate (DDR) memory architectures, and the physical interface and circuitry responsible for managing the data transfer between a DDR may controller and the DDR memory itself (e.g., DDR PHY). However, it will be recognized, based on the teachings of the present disclosure, that the aspects of the disclosure may be employed in different types of multichip modules having different integrated circuit packages.

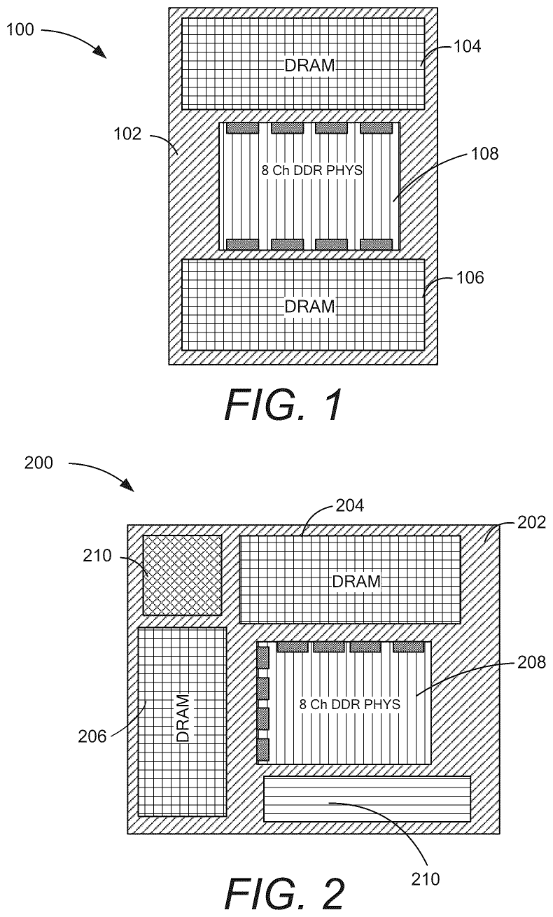

FIG. 1 shows an example DDR memory module 100, according to aspects of the disclosure. In this example, the DDR memory module 100 includes a substrate 102 supporting and interconnecting the integrated circuit packages of the DDR memory module 100. Two DRAM integrated circuit packages 104 and 106 are disposed on opposite sides of an 8-channel DDR PHYS integrated circuit package 108. Although the DDR memory module 100 is suitable for many applications, the signal integrity and crosstalk interference (SICI) penalties associated with the manner in which the components are interconnected in this architecture increase with the clock frequency and may render the architecture unsuitable for high-speed applications.

FIG. 2 shows an example DDR memory module 200, according to aspects of the disclosure. In this example, the DDR memory module 200 includes a substrate 202 supporting and interconnecting the integrated circuit packages of the DDR memory module 200. Here, two DRAM integrated circuit packages 204 and 206 are disposed at adjacent sides of an 8-channel DDR PHYS integrated circuit package 208. By placing the DRAM integrated circuit packages at DDR channels disposed on adjacent sides of the DDR PHYS integrated circuit package, the SICI penalties associated with high-speed operation of the DDR memory module are reduced. However, the architecture of the DDR memory module 200 is wasteful of the real estate occupied by the substrate 202, as shown by the unused substrate regions 210.

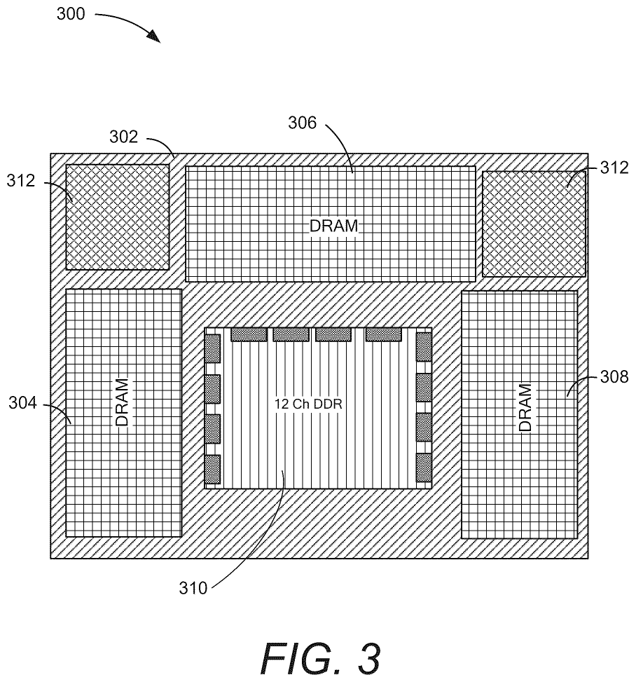

As the memory storage needs of an electronic system increase, additional DRAM integrated circuit packages and DDR PHYS with a higher number of channels may be needed. FIG. 3 shows an example DDR memory module 300, according to aspects of the disclosure. In this example, the DDR memory module 300 includes a substrate 302 interconnecting and supporting the integrated circuit packages of the DDR memory module 300. Here, three DRAM integrated circuit packages 304, 306, and 308 are disposed at adjacent sides of a 12-channel DDR PHYS 310. Since the DRAM integrated circuit packages are disposed on adjacent sides of the DDR PHYS integrated circuit package, the SICI penalties associated with high-speed operation of the DDR memory module may be reduced. However, the real estate occupied by the substrate 302 is not efficiently utilized given the continued presence of the unused substrate regions 312.

Certain aspects of the disclosure are directed to a multichip module having multiple integrated circuits disposed on a folded substrate. In an aspect, the multichip module includes one or more integrated circuit packages connected to a central region of the folded substrate and one or more integrated circuit packages connected to flaps of the folded substrate that are folded over the central region.

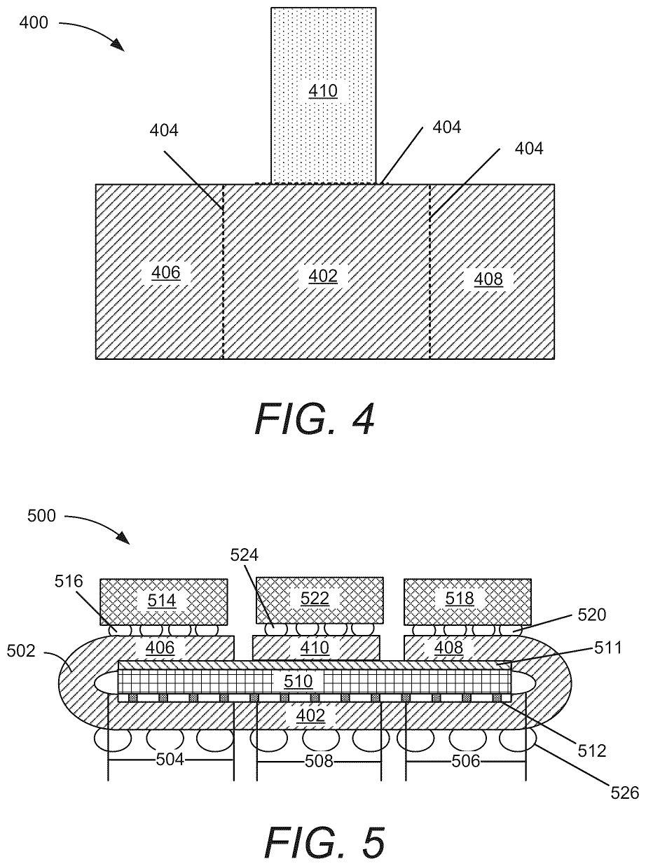

FIG. 4 is a plan view of an example foldable substrate 400 that may be used in a multichip module, according to aspects of the disclosure. Here, the foldable substrate 400 includes a central region 402 having bend lines 404 separating the central region 402 from flaps that are disposed adjacent to the central region 402. In this example, a first flap 406 and a second flap 408 are disposed at opposite sides of the central region 402. Additionally, a third flap 410 is disposed at a third side of the central region 402 and is oriented perpendicular to the first flap 406 and the second flap 408.

FIG. 5 is a cross-sectional view of a multichip module 500, according to aspects of the disclosure. The multichip module 500 includes a folded substrate 502 formed by folding the foldable substrate 400 along bend lines in the described manner. Here, the first flap 406 is folded at a bend line to overlie at least a first portion 504 of the central region 402 of the folded substrate 502. The second flap 408 is folded at a bend line to overlie a second portion 506 of the central region 402 of the folded substrate 502. Additionally, the third flap 410 is folded at a bend line to overlie a third portion 508 of the central region 402 of the folded substrate 502.

In FIG. 5, the multichip module 500 includes four integrated circuit packages. As shown, a first integrated circuit package 510 is electrically connected to the folded substrate 502 at an interior surface of the central region 402 of the folded substrate 502 (e.g., by electrical contacts 512). In this example, an interior surface of the first flap 406 overlies at least a portion of the first integrated circuit package 510. Similarly, an interior surface of the second flap 408 overlies a further portion of the first integrated circuit package 510. A layer 511 of a thermal interface material may be formed over an upper surface of the first integrated circuit package 510 and the interior facing surfaces of the flaps 406, 408, and 410. In an aspect, the first integrated circuit package 510 may be a DDR PHYS integrated circuit package.

Additionally, a second integrated circuit package 514 is electrically connected to an outer surface of the first flap 406 of the folded substrate 502 (e.g., by electrical contacts 516). A third integrated circuit package 518 is electrically connected to an outer surface of the second flap 408 of the folded substrate 502 (e.g., by electrical contacts 520). A fourth integrated circuit package 522 is electrically connected to an outer surface of the third flap 410 of the folded substrate 502 (e.g., by electrical contacts 522). Here, the third flap 410 is dimensioned to fold over the first integrated circuit package 510 into a region between the edges of the first flap 406 and the second flap 408. In an aspect, each of the integrated circuit packages 514, 518, and 522 may be DRAM integrated circuit packages.

According to aspects of the disclosure, contacts (e.g., contacts of a ball grid array 526) are formed at a lower exterior surface of the multichip module 500. The contacts of the ball grid array 526 may facilitate electrical connection to other components of an electronic system. In an aspect, the multichip module 500 may be electrically connected and mounted to a further substrate, such as a printed circuit substrate.

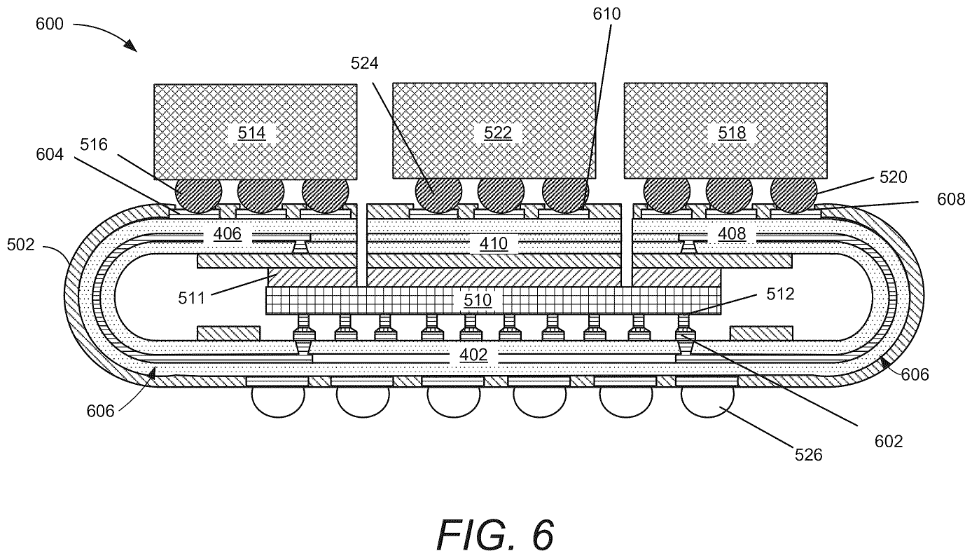

FIG. 6 is a cross-sectional view of a multichip module 600, according to aspects of the disclosure. Here, the cross-section of view of the multichip module 600 illustrates various metallizations that provide the necessary electrical interconnections between the integrated circuit packages 510, 514, 518, 522, and the ball gate array 526. In FIG. 6, the contacts 512 of the first integrated circuit package 510 are electrically connected to contact elements 602 at the interior surface of the central region 402 and, therefrom, through metallizations formed in the folded substrate 502 that electrically interconnect the contact elements 602 with other portions of the multichip module 600. The contacts 516 of the second integrated circuit package 514 are electrically connected to contact pads 604 at the exterior surface of the first flap 406 and, therefrom, through metallizations (e.g., one or more metallization layers 606) formed in the folded substrate 502 that electrically interconnect the contact pads 604 with other portions of the multichip module 600. The electrical contacts 520 of the third integrated circuit package 518 are electrically connected to contact pads 608 at the exterior surface of the second flap 408 and, therefrom, through metallizations formed in the folded substrate 502 that electrically interconnect the contact pads 608 with other portions of the multichip module 600. The contacts 524 of the fourth integrated circuit package 522 are electrically connected to contact pads 610 at the exterior surface of the third flap 410 and, therefrom, through metallizations formed in the folded substrate 502 that electrically interconnect the contact pads 608 with other portions of the multichip module 600.

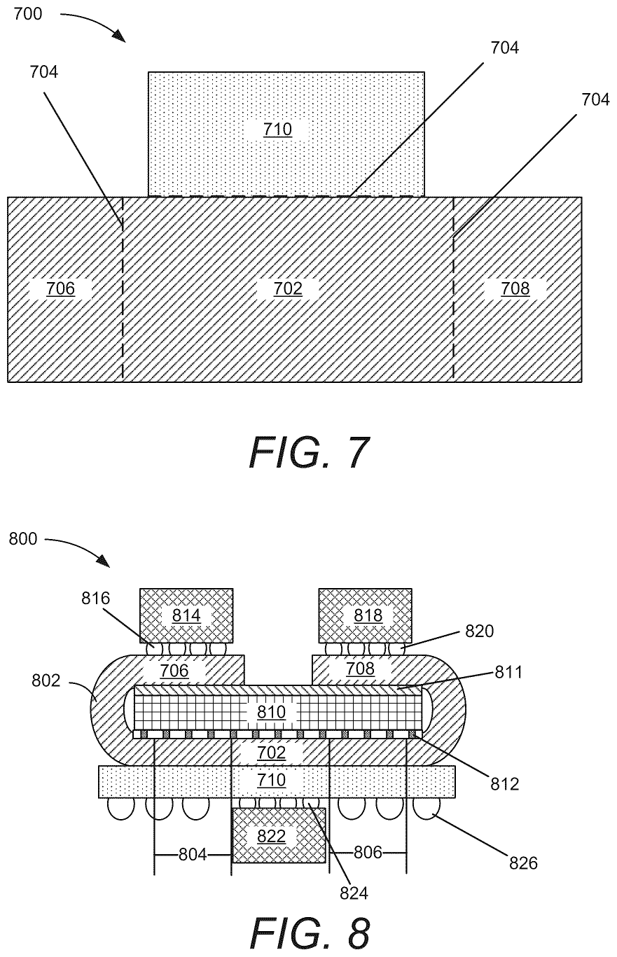

FIG. 7 is a plan view of an example foldable substrate 700 that may be used in a multichip module, according to aspects of the disclosure. Here, the foldable substrate 700 includes a central region 702 having bend lines 704 separating the central region 702 from flaps that are disposed adjacent to the central region 702. In this example, a first flap 706 and a second flap 708 are disposed at opposite sides of the central region 702. Additionally, a third flap 710 is disposed at a third side of the central region 702 and is oriented perpendicular to the first flap 706 and the second flap 708.

FIG. 8 is a cross-sectional view of a multichip module 800, according to aspects of the disclosure. The multichip module 800 includes a folded substrate 802 formed by folding the foldable substrate 700 along bend lines in the described manner. Here, the first flap 706 is folded at a bend line to overlie at least a first portion 804 of the central region 702 of the folded substrate 802. The second flap 708 is folded at a bend line to overlie a second portion 806 of the central region 702 of the folded substrate 802. Unlike the example multichip module 500 shown in FIG. 5, the third flap 710 is folded backward at a bend line so that it is adjacent to an exterior portion of the central region 702 of the folded substrate 802.

In FIG. 8, the multichip module 800 includes four integrated circuit packages. As shown, a first integrated circuit package 810 is electrically connected to the folded substrate 802 at an interior surface of the central region 702 of the folded substrate 802 (e.g., by electrical contacts 812). In this example, an interior surface of the first flap 706 overlies at least a portion of the first integrated circuit package 810. Similarly, an interior surface of the second flap 708 overlies a further portion of the first integrated circuit package 810. A layer 811 of a thermal interface material may be formed between an upper surface of the first integrated circuit package 810 and the interior facing surfaces of the flaps 706 and 708. In an aspect, the first integrated circuit package 810 may be a DDR PHYS integrated circuit package.

Additionally, a second integrated circuit package 814 is electrically connected to an outer surface of the first flap 706 of the folded substrate 802 (e.g., by electrical contacts 816). A third integrated circuit package 818 is electrically connected to an outer surface of the second flap 708 of the folded substrate 802 (e.g., by electrical contacts 820). A fourth integrated circuit package 822 is electrically connected to an outer surface of the third flap 710 of the folded substrate 802 (e.g., by electrical contacts 824).

According to aspects of the disclosure, contacts (e.g., contacts of a ball grid array 826) may be formed at a lower exterior surface (e.g., over an exterior surface of the third flap 710) of the multichip module 800. The contacts of the ball grid array 826 may facilitate physical and electrical connections to other components of an electronic system. In an aspect, the multichip module 800 may be electrically connected and mounted to a further substrate, such as a printed circuit substrate.

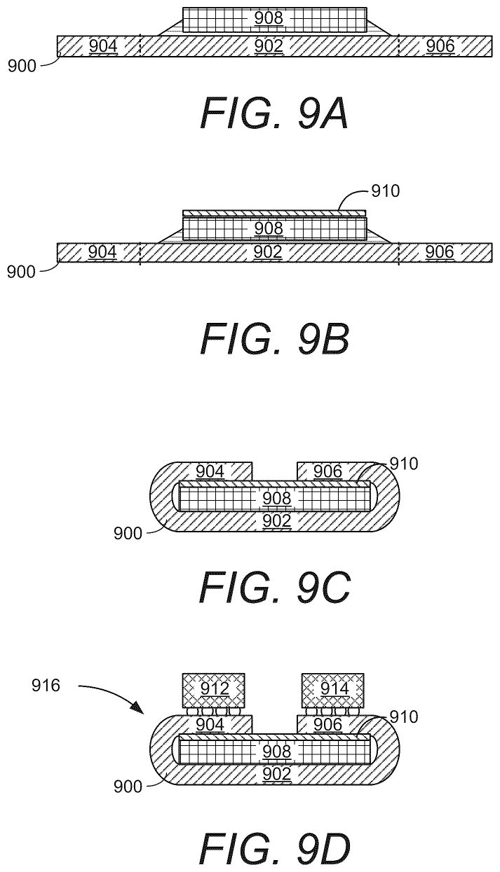

FIG. 9A through FIG. 9D illustrate example processing operations that may be used to fabricate a multichip module, according to aspects of the disclosure. In FIG. 9A, a foldable substrate 900 is provided that has been previously processed to include the contacts and metallizations that electrically interconnect the components of the multichip module. As shown, the foldable substrate 900 includes a central region 902, a first flap 904, and a second flap 906. A first integrated circuit package 908 is subject to a die attachment and underfill process to mount and electrically connect the first integrated circuit package 908 to central region 902 of the substrate 900. At FIG. 9B, an adhesive layer 910 of a thermal interface material (TIM) is formed over the upper surface of the first integrated circuit package 908. At FIG. 9C, the flaps 904 and 906 are folded over the adhesive layer 910 and subject to a thermal compression operation to secure the flaps 904 and 906 over the first integrated circuit package 908. At FIG. 9D, a second integrated circuit package 912 is connected to the first flap 904, and a third integrated circuit package 914 is connected to the second flap 906 using, for example, surface mount technology. The foregoing operations result in an intermediate structure 916 that is subject to further processing operations depending on whether the multichip module is to result in the first example architecture of the multichip module 500 of FIG. 5 or the second example architecture of the multichip module 800 of FIG. 8.

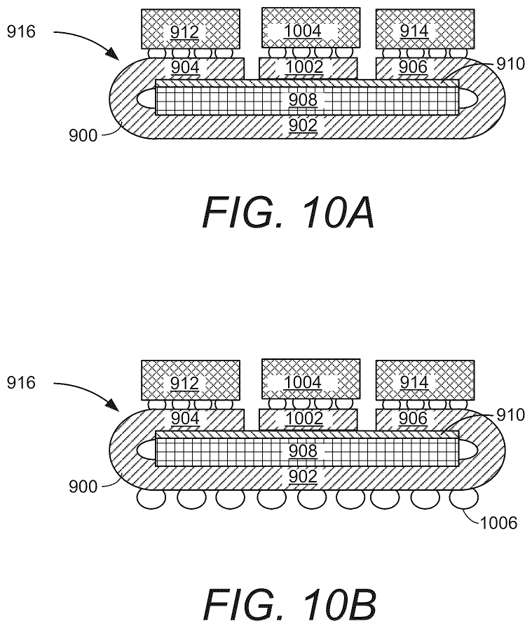

FIG. 10A and FIG. 10B illustrate example processing operations that may be performed in forming the first example architecture of the multichip module, according to aspects of the disclosure. In FIG. 10A, a third flap 1002 of the foldable substrate 900 is folded over the adhesive layer 910 and subject to a thermal compression operation to secure the third flap 1002 and an upper surface of the first integrated circuit package 908. Additionally, a fourth integrated circuit package 1004 is mounted and electrically connected to the third flap 1002. In FIG. 10B, contacts 1006 (e.g., a ball grid array) are formed over a lower exterior surface of the substrate 900.

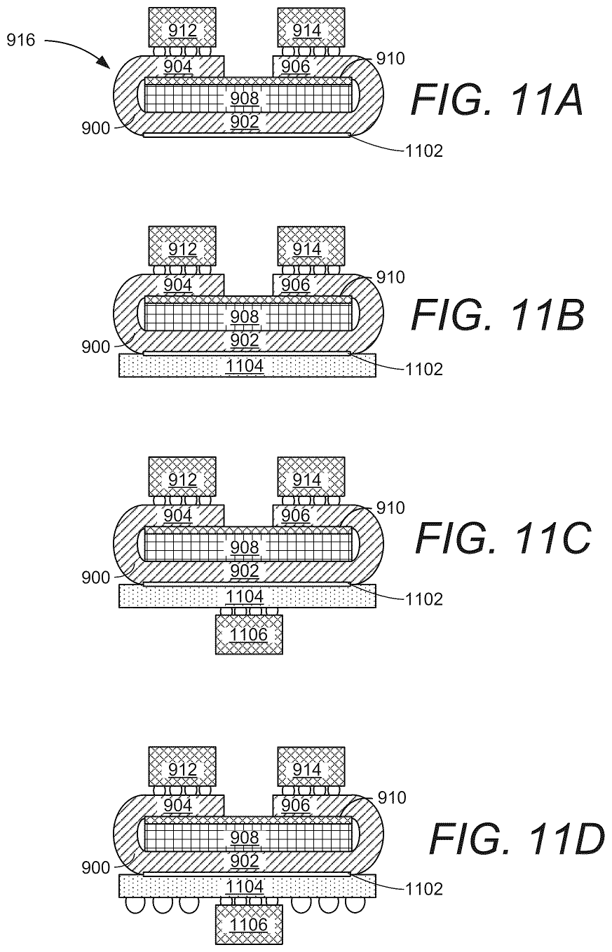

FIG. 11A through FIG. 11D illustrate example processing operations that may be performed in forming the second example architecture of the multichip module, according to aspects of the disclosure. In FIG. 11A, an adhesive layer 1102 of a thermal interface material is formed over a lower exterior surface of the foldable substrate 900. In FIG. 11B, a third flap 1104 of the foldable substrate 900 is folded backward over the adhesive layer 1102 and subject to a thermal compression operation to secure the third flap 1104 at a lower surface of the central region 902 of the foldable substrate 900. In FIG. 11C, a fourth integrated circuit package 1106 is mounted and electrically connected to the third flap 1104. In FIG. 11D, contacts 1006 (e.g., a ball grid array) are formed over a lower exterior surface of the substrate 900.

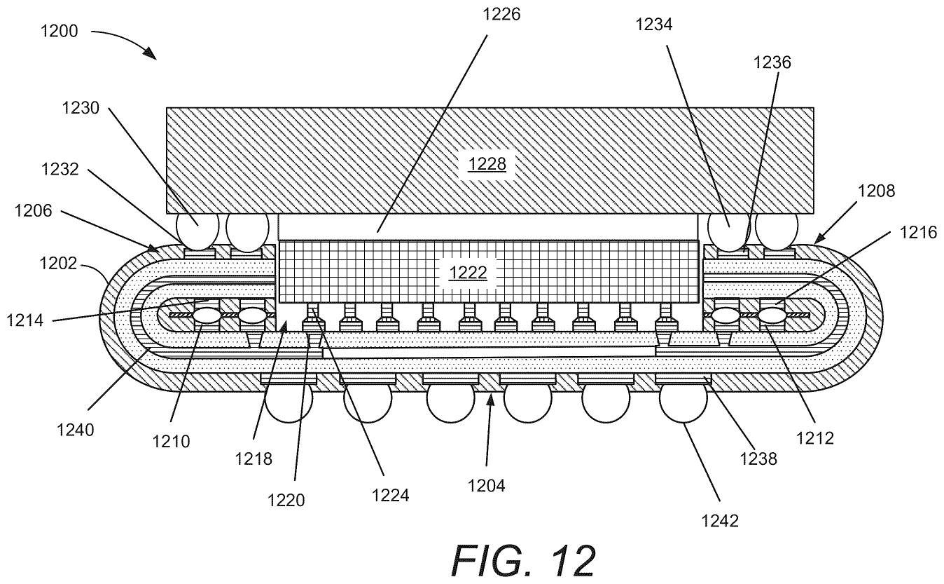

FIG. 12 illustrates another example of a multichip module 1200, according to aspects of the disclosure. In this example, the multichip module 1200 includes a folded substrate 1202 having a central region 1204, a first flap 1206 adjacent to a first side portion of the central region 1204, and a second flap 1208 adjacent to a second side portion of the central region 1204. The central region 1204 includes a set of contacts 1210 at an inner surface of the first side portion and a set of one or more contacts 1212 at an inner surface of the second side portion of the central region 1204. The first flap 1206 includes a set of one or more contacts 1214 at its inner surface. Likewise, the second flap 1208 includes a set of one or more contacts 1216 at its inner surface. The first flap 1206 is folded along a bend line at the first side portion of the central region 1204 so that the contacts 1214 overlie the contacts 1210 while the second flap 1208 is folded along a bend line and the second side portion of the central region 1204 so that the contacts 1216 overlie the contacts 1212. In this configuration, the contacts 1214 and the contacts 1210 are placed in electrical contact with one another, either directly or through an intermediate conductive structure (e.g., conductive paste). Similarly, the contacts 1216 and the contacts 1212 are placed in electrical contact with one another, either directly or through an intermediate conductive structure.

In FIG. 12, a first integrated circuit package 1222 is electrically connected through package contacts 1224 to a set of one or more contacts 1220 at an interior surface of the central region 1204. In an aspect, the first integrated circuit package 1222 is disposed in an open region 1218 formed between edges of the first flap 1206 and the second flap 1208. A set of one or more metallizations 1240 may be formed in the folded substrate 1202 to electrically connect two or more of the first set of one or more contacts 1210, the second set of one or more contacts 1212, the third set of one or more contacts 1214, the fourth set of one or more contacts 1216, and fifth set of one or more contacts 1220 with one another.

In an aspect, a second integrated circuit package 1228 is electrically connected through contacts 1230 to a set of one or more contacts 1232 disposed at an exterior surface of the first flap 1206. Additionally, the second integrated circuit package 1228 may be connected through contacts 1234 to a set of one or more contacts 1236 at an exterior surface of the second flap 1208. A layer of thermal interface material 1226 may be disposed between the upper surface of the first integrated circuit package 1222 and the lower surface of the second integrated circuit package 1228.

In an aspect, the multichip module 1200 may include contacts 1238 at a lower surface of the central region 1204. A ball grid array 1242 may be formed at the contact 1238 to facilitate mounting of the multichip module 1200 to a further substrate, such as a printed circuit board.

The architecture of the multichip module 1200 may be used to fabricate various electronic module types, including a variety of combinations of integrated circuit packages that have different electronic functions. In an aspect, the first integrated circuit package 1222 may be a system on a chip integrated circuit package, a DDR PHY integrated circuit package, or the like. In an aspect, the second integrated circuit package 1228 may be a memory integrated circuit package such as a DRAM integrated circuit package. Based on the teachings of the present disclosure, it will be recognized that other combinations of integrated circuit packages may be incorporated based on the specified functionality and purpose of the multichip module 1200.

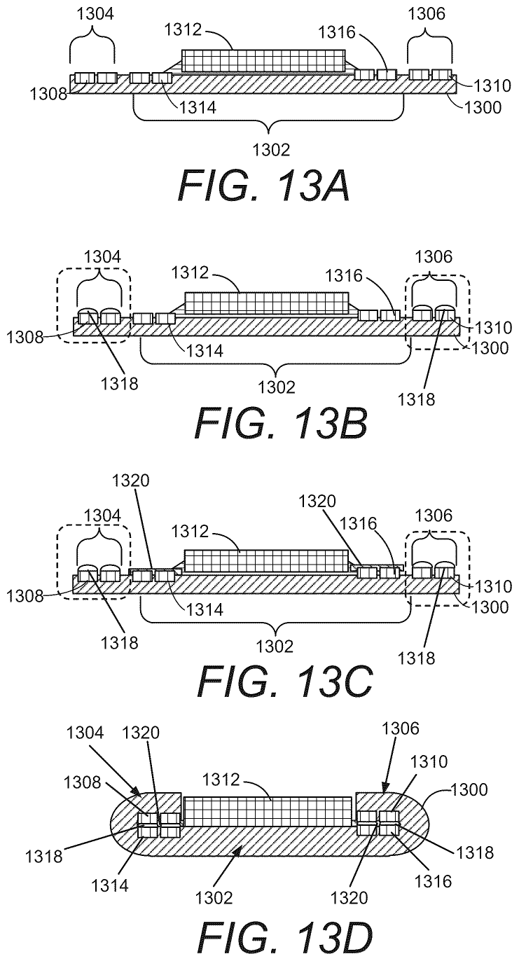

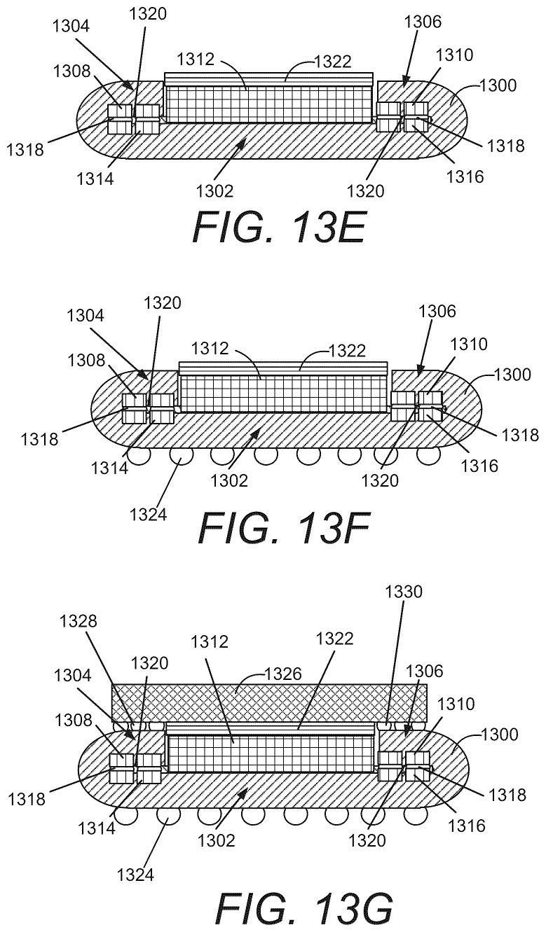

FIG. 13A through FIG. 13G illustrate example processing operations that may be used to fabricate a multichip module, according to aspects of the disclosure. In FIG. 13A, a foldable substrate 1300 is provided that has been previously processed to include the contacts and other metallizations that will electrically interconnect the components of the multichip module. As shown, the foldable substrate 1300 includes a central region 1302, a first flap 1304, and a second flap 1306. The foldable substrate 1300 includes a set of contacts 1308 at what will become the interior surface of the first flap 1304. Likewise, the foldable substrate 1300 includes a set of contacts 1310 at what will become the interior surface of the second flap 1306.

A first integrated circuit package 1312 is mounted on and electrically connected to the foldable substrate 1300. In an aspect, the first integrated circuit package 1312 and central region 1302 of the foldable substrate 1300 include contacts (not shown) that electrically connect the integrated circuit package 1312 with the metallizations formed in the foldable substrate 1300 (not shown). A set of contacts 1314 are disposed at a first side portion of the central region 1302 adjacent to the first integrated circuit package 1312. Additionally, a set of contacts 1316 is disposed at a second side portion of the central region 1302 adjacent the first integrated circuit package 1312.

In FIG. 13B, a conductive paste 1318 is deposited on (e.g., printed on) the set of contacts 1308 and the set of contacts 1314. In FIG. 13C, a non-conductive paste 1320 is deposited on (e.g., printed on) the set of contacts 1314 and the set of contacts 1316.

In FIG. 13D, the first flap 1304 is folded over to place the set of contacts 1308 in electrical contact with the set of contacts 1314. Similarly, the second flap 1306 is folded over to place the set of contacts 1310 in electrical contact with the set of contacts 1316. In each instance, the conductive paste 1318 facilitates the electrical connection between the contacts, while the non-conductive paste 1320 is disposed between the contacts to prevent short-circuiting. In an aspect, the folding operation may include a thermal compression process.

In FIG. 13E, a layer of a thermal interface material 1322 is formed over an upper surface of the first integrated circuit package 1312. In an aspect, the thermal interface material 1322 may be dispensed over the upper surface of the first integrated circuit package 1312 or attached as a preform.

In FIG. 13F, a set of contacts 1324 (e.g., a ball gate array) is formed at an exterior surface of the central region 1302 of the folded substrate 1300. In FIG. 13G, a second integrated circuit package 1326 is stacked on the foldable substrate 1300. In this example, the second integrated circuit package 1326 includes a set of contacts 1328 that are electrically connected to a corresponding set of contacts at the exterior surface of the first flap 1304. Likewise, the second integrated circuit package 1326 includes a set of contacts 1330 that are electrically connected to a corresponding set of contacts at the exterior surface of the first flap 1304.

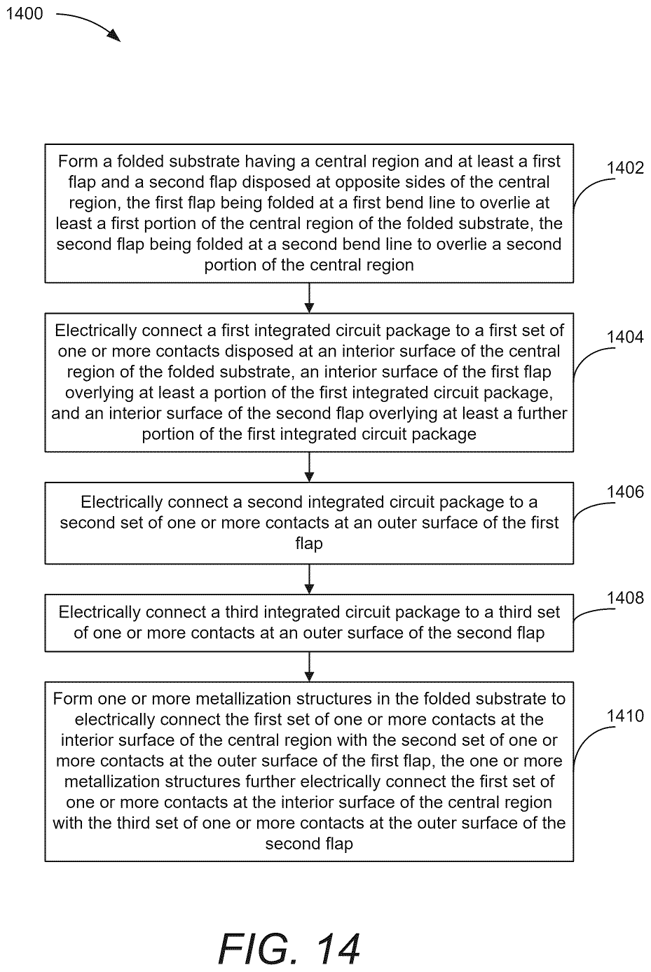

FIG. 14 shows an example method of fabricating a multichip module, according to aspects of the disclosure. At operation 1402, a folded substrate is formed having a central region and at least a first flap and a second flap disposed at opposite sides of the central region, the first flap being folded at a first bend line to overlie at least a first portion of the central region of the folded substrate, the second flap being folded at a second bend line to overlie a second portion of the central region. At operation 1404, a first integrated circuit package is electrically connected to a first set of one or more contacts disposed at an interior surface of the central region of the folded substrate, an interior surface of the first flap overlying at least a portion of the first integrated circuit package, and an interior surface of the second flap overlying at least a further portion of the first integrated circuit package. At operation 1406, a second integrated circuit package is electrically connected to a second set of one or more contacts at an outer surface of the first flap. At operation 1408, a third integrated circuit package is electrically connected to a third set of one or more contacts at an outer surface of the second flap. At operation 1410, one or more metallizations are formed in the folded substrate to electrically connect the first set of one or more contacts at the interior surface of the central region with the second set of one or more contacts at the outer surface of the first flap, the one or more metallizations further electrically connect the first set of one or more contacts at the interior surface of the central region with the third set of one or more contacts at the outer surface of the second flap.

A technical advantage of the method 1400 is that it provides a multichip module having a small form factor with an efficient and short pipe length path for PHYS DDR placement on a silicon-on-chip (SOC). Additionally, the multichip module fabricated using the method 1400 may be configured to improve power distribution for DRAM applications since ball/joint interconnections may be avoided thereby providing a continuous power path for return and power shapes. Still, further, insertion loss may be reduced based on the continuous geometry of the wiring.

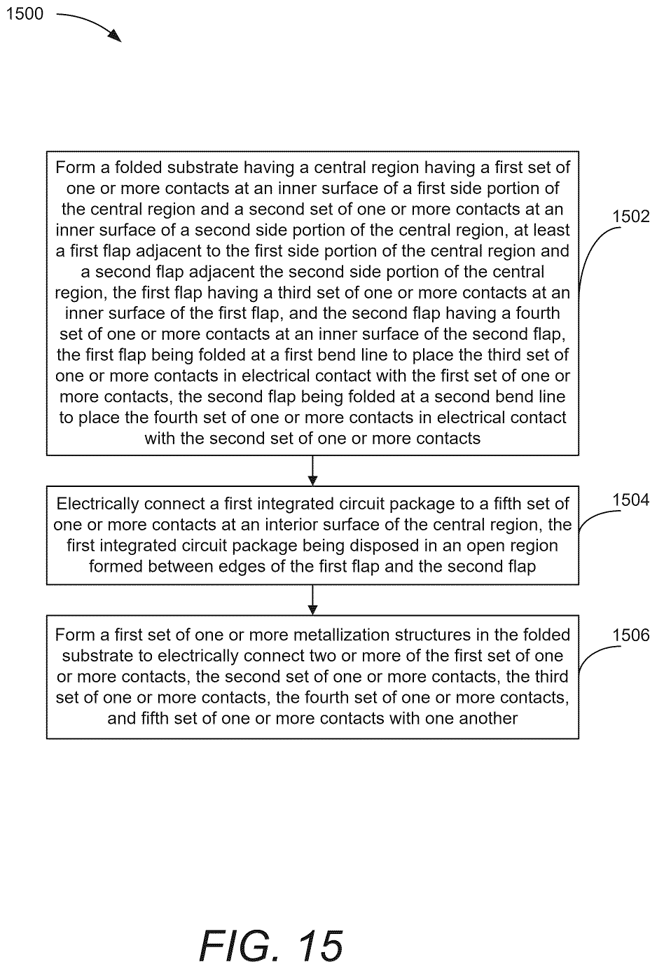

FIG. 15 shows an example method of fabricating a multichip module, according to aspects of the disclosure. At operation 1502, a folded substrate is formed having a central region having a first set of one or more contacts at an inner surface of a first side portion of the central region and a second set of one or more contacts at an inner surface of a second side portion of the central region, at least a first flap adjacent to the first side portion of the central region and a second flap adjacent the second side portion of the central region, the first flap having a third set of one or more contacts at an inner surface of the first flap, and the second flap having a fourth set of one or more contacts at an inner surface of the second flap, the first flap being folded at a first bend line to place the third set of one or more contacts in electrical contact with the first set of one or more contacts, the second flap being folded at a second bend line to place the fourth set of one or more contacts in electrical contact with the second set of one or more contacts. At operation 1504, a first integrated circuit package is electrically connected to a fifth set of one or more contacts at an interior surface of the central region, the first integrated circuit package being disposed in an open region formed between the edges of the first flap and the second flap. At operation 1506, a first set of one or more metallizations are formed in the folded substrate to electrically connect two or more of the first set of one or more contacts, the second set of one or more contacts, the third set of one or more contacts, the fourth set of one or more contacts, and fifth set of one or more contacts with one another.

A technical advantage of the method 1500 is that it provides a multichip module having a small form factor with an efficient and short pipe length path for PHYS DDR placement on a silicon-on-chip (SOC). Additionally, a multichip module according to the method 1500 may be configured to improve power distribution for DRAM applications since ball/joint interconnections may be avoided thereby providing a continuous power path for return and power shapes. Still, further, insertion loss may be reduced based on the continuous geometry of the wiring.

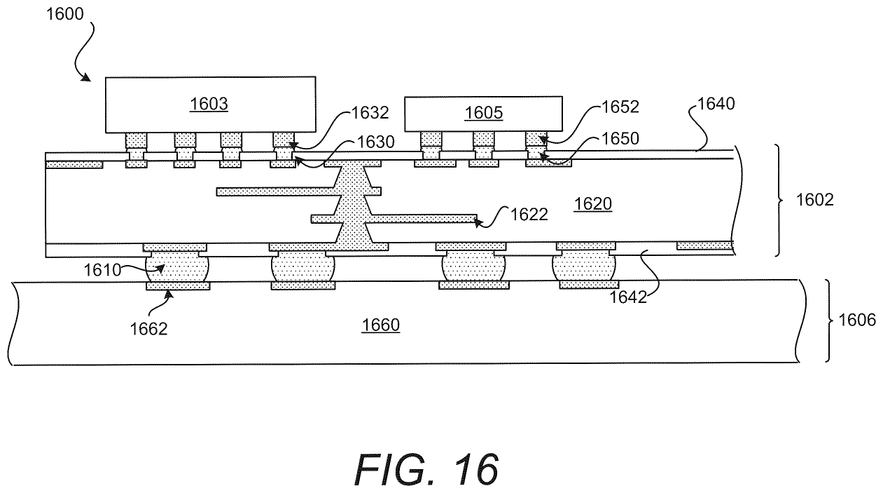

FIG. 16 illustrates a profile view of a package 1600 that includes a surface mount substrate 1602, an integrated device 1603, and a multichip module 1605, according to aspects of the disclosure. The package 1600 may be coupled to a printed circuit board (PCB) 1606 through a plurality of solder interconnects 1610. The PCB 1606 may include at least one board dielectric layer 1660 and a plurality of board interconnects 1662.

The surface mount substrate 1602 includes at least one dielectric layer 1620 (e.g., substrate dielectric layer), a plurality of interconnects 1622 (e.g., substrate interconnects), a solder resist layer 1640 and a solder resist layer 1642. The integrated device 1603 may be coupled to the surface mount substrate 1602 through a plurality of solder interconnects 1630. The integrated device 1603 may be coupled to the surface mount substrate 1602 through a plurality of pillar interconnects 1632 and the plurality of solder interconnects 1630. The multichip module 1605 may be coupled to the surface mount substrate 1602 through a plurality of solder interconnects 1650. The multichip module 1605 may be coupled to the surface mount substrate 1602 through a plurality of pillar interconnects 1652 and the plurality of solder interconnects 1650.

The package (e.g., 1600) may be implemented in a radio frequency (RF) package. The RF package may be a radio frequency front end (RFFE) package. A package (e.g., 1600) may be configured to provide Wireless Fidelity (WiFi) communication and/or cellular communication (e.g., 2G, 3G, 4G, 5G). The package (e.g., 1600) may be configured to support Global System for Mobile (GSM) Communications, Universal Mobile Telecommunications System (UMTS), and/or Long-Term Evolution (LTE). The package (e.g., 1600) may be configured to transmit and receive signals having different frequencies and/or communication protocols.

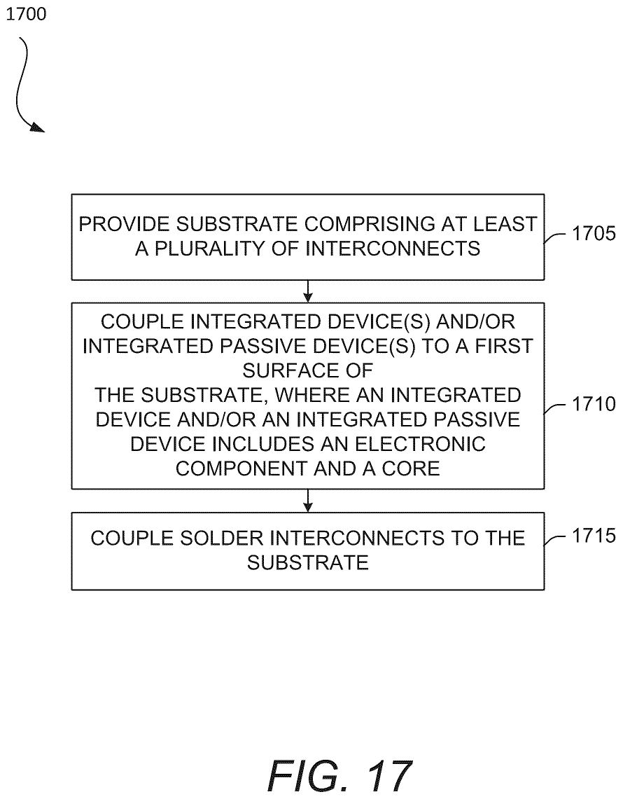

FIG. 17 illustrates an example method 1700 for providing or fabricating a package that includes an integrated device comprising an electronic component mounted in a core, according to aspects of the disclosure. In some implementations, the method 1700 of FIG. 17 may be used to provide or fabricate the package 1600 of FIG. 16 described in the disclosure. However, the method 1700 may be used to provide or fabricate any of the packages described in the disclosure.

It should be noted that the method of FIG. 17 may combine one or more processes in order to simplify and/or clarify the method for providing or fabricating a package that includes an integrated device comprising an electronic component mounted in a core, according to aspects of the disclosure. In some implementations, the order of the processes may be changed or modified.

The method provides (at 1705) a substrate (e.g., 1602). The substrate 1602 may be provided by a supplier or fabricated. The substrate 1602 includes at least one dielectric layer 1620 and a plurality of interconnects 1622. The substrate 1602 may include an embedded trace substrate (ETS). In some implementations, the at least one dielectric layer 1620 may include prepreg layers.

The method couples (at 1710) at least one integrated device (e.g., 1603) to the first surface of the substrate (e.g., 1602). For example, the integrated device 1603 may be coupled to the substrate 1602 through the plurality of pillar interconnects 1632 and the plurality of solder interconnects 1630. The plurality of pillar interconnects 1632 may be optional. The plurality of solder interconnects 1630 are coupled to the plurality of interconnects 1622. A solder reflow process may be used to couple the integrated device 1603 to the plurality of interconnects through the plurality of solder interconnects 1630.

The method also couples (at 1710) at least one integrated device (e.g., multichip module 1605) to the first surface of the substrate (e.g., 1602). For example, the multichip module 1605 may be coupled to the substrate 1602 through the plurality of pillar interconnects 1652 and the plurality of solder interconnects 1650. The plurality of pillar interconnects 1652 may be optional. The plurality of solder interconnects 1650 are coupled to the plurality of interconnects 1622. A solder reflow process may be used to couple the multichip module 1605 to the plurality of interconnects through the plurality of solder interconnects 1650.

The method couples (at 1715) a plurality of solder interconnects (e.g., 1610) to the second surface of the substrate (e.g., 1602). A solder reflow process may be used to couple the plurality of solder interconnects 1610 to the substrate.

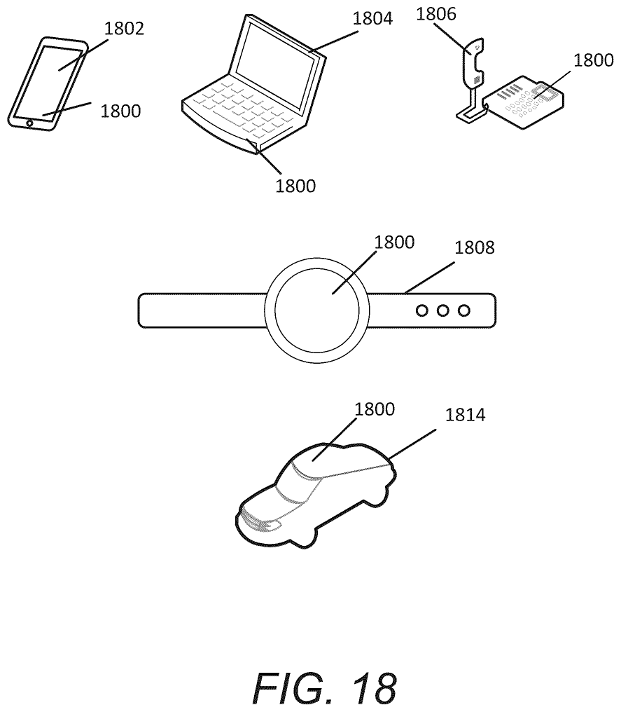

FIG. 18 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 1802, a laptop computer device 1804, a fixed location terminal device 1806, a wearable device 1808, or automotive vehicle 1814 may include a device 1800 as described herein. The device 1800 may be, for example, any of the devices and/or integrated circuit (IC) packages described herein. The devices 1802, 1804, 1806 and 1808 and the vehicle 1810 illustrated in FIG. 18 are merely exemplary. Other electronic devices may also feature the device 1800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:
Aspect 1. An electronic device, comprising: a multichip module comprising a folded substrate having a central region and at least a first flap and a second flap disposed at opposite sides of the central region, the first flap being folded at a first bend line to overlie at least a first portion of the central region of the folded substrate, the second flap being folded at a second bend line to overlie a second portion of the central region; a first integrated circuit package electrically connected to a first set of one or more contacts disposed at an interior surface of the central region of the folded substrate, an interior surface of the first flap overlying at least a portion of the first integrated circuit package, and an interior surface of the second flap overlying at least a further portion of the first integrated circuit package; a second integrated circuit package electrically connected to a second set of one or more contacts at an outer surface of the first flap; a third integrated circuit package electrically connected to a third set of one or more contacts at an outer surface of the second flap; and one or more metallizations formed in the folded substrate to electrically connect the first set of one or more contacts at the interior surface of the central region with the second set of one or more contacts at the outer surface of the first flap, the one or more metallizations further electrically connect the first set of one or more contacts at the interior surface of the central region with the third set of one or more contacts at the outer surface of the second flap.
Aspect 2. The electronic device of aspect 1, further comprising: a non-conductive layer of a thermal interface material disposed between an exterior surface of the first integrated circuit package and the interior surface of the first flap and between the exterior surface of the first integrated circuit package and the interior surface of the second flap.
Aspect 3. The electronic device of any of aspects 1 to 2, wherein: the second integrated circuit package and the third integrated circuit package each comprise dynamic random access memory (DRAM); and the first integrated circuit package comprises a DRAM physical interface (PHYs).
Aspect 4. The electronic device of any of aspects 2 to 3, further comprising: a third flap folded at a third bend line to overlie at least a third portion of the central region of the folded substrate between the first flap and the second flap; a fourth integrated circuit package electrically connected to a fourth set of one or more contacts at an exterior surface of the third flap; and wherein the one or more metallizations further electrically connect the fourth set of one or more contacts with the first set of one or more contacts.
Aspect 5. The electronic device of any of aspects 3 to 4, wherein: the second integrated circuit package, the third integrated circuit package, and fourth integrated circuit package each comprise dynamic random access memory (DRAM); and the first integrated circuit package comprises a DRAM physical interface (PHYs).
Aspect 6. The electronic device of any of aspects 1 to 5, further comprising: a third flap folded at a third bend line to underlie at least a portion of the central region of the folded substrate; a fourth integrated circuit package electrically connected to a fourth set of one or more contacts at an exterior surface of the third flap; and wherein the one or more metallizations electrically connect the fourth set of one or more contacts with the first set of one or more contacts.
Aspect 7. The electronic device of any of aspects 5 to 6, wherein: the second integrated circuit package, the third integrated circuit package, and fourth integrated circuit package each comprise dynamic random access memory (DRAM); and the first integrated circuit package comprises a DRAM physical interface (PHYs).
Aspect 8. The electronic device of any of aspects 1 to 7, further comprising: a fourth set of one or more contacts disposed at an exterior surface of the central region; and a further set of one or more metallizations formed in the folded substrate electrically connect the first set of one or more contacts and the fourth set of one or more contacts.
Aspect 9. The electronic device of any of aspects 1 to 8, wherein the electronic device comprises at least one of: a music player; a video player; an entertainment unit; a navigation device; a communications device; a mobile device; a mobile phone; a smartphone; a personal digital assistant; a fixed location terminal; a tablet computer, a computer; a wearable device; a laptop computer; a server; an internet of things (IoT) device; or a device in an automotive vehicle.
Aspect 10. A multichip module, comprising a folded substrate having a central region and at least a first flap and a second flap disposed at opposite sides of the central region, the first flap being folded at a first bend line to overlie at least a first portion of the central region of the folded substrate, the second flap being folded at a second bend line to overlie a second portion of the central region; a first integrated circuit package electrically connected to a first set of one or more contacts disposed at an interior surface of the central region of the folded substrate, an interior surface of the first flap overlying at least a portion of the first integrated circuit package, and an interior surface of the second flap overlying at least a further portion of the first integrated circuit package; a second integrated circuit package electrically connected to a second set of one or more contacts at an outer surface of the first flap; a third integrated circuit package electrically connected to a third set of one or more contacts at an outer surface of the second flap; and one or more metallizations formed in the folded substrate to electrically connect the first set of one or more contacts at the interior surface of the central region with the second set of one or more contacts at the outer surface of the first flap, the one or more metallizations further electrically connect the first set of one or more contacts at the interior surface of the central region with the third set of one or more contacts at the outer surface of the second flap.
Aspect 11. The multichip module of aspect 10, further comprising: a non-conductive layer of a thermal interface material disposed between an exterior surface of the first integrated circuit package and the interior surface of the first flap and between the exterior surface of the first integrated circuit package and the interior surface of the second flap.
Aspect 12. The multichip module of any of aspects 10 to 11, wherein: the second integrated circuit package and the third integrated circuit package each comprise dynamic random access memory (DRAM); and the first integrated circuit package comprises a DRAM physical interface (PHYs).
Aspect 13. The multichip module of aspect 12, further comprising: a third flap folded at a third bend line to overlie at least a third portion of the central region of the folded substrate between the first flap and the second flap; a fourth integrated circuit package electrically connected to a fourth set of one or more contacts at an exterior surface of the third flap; and wherein the one or more metallizations further electrically connect the fourth set of one or more contacts with the first set of one or more contacts.
Aspect 14. The multichip module of aspect 13, wherein: the second integrated circuit package, the third integrated circuit package, and fourth integrated circuit package each comprise dynamic random access memory (DRAM); and the first integrated circuit package comprises a DRAM physical interface (PHYs).
Aspect 15. The multichip module of claim 10, further comprising: a third flap folded at a third bend line to underlie at least a portion of the central region of the folded substrate; a fourth integrated circuit package electrically connected to a fourth set of one or more contacts at an exterior surface of the third flap; and wherein the one or more metallizations electrically connect the fourth set of one or more contacts with the first set of one or more contacts.
Aspect 16. The multichip module of aspect 15, wherein: the second integrated circuit package, the third integrated circuit package, and fourth integrated circuit package each comprise dynamic random access memory (DRAM); and the first integrated circuit package comprises a DRAM physical interface (PHYs).
Aspect 17. The multichip module of any of aspects 10 to 16, further comprising: a fourth set of one or more contacts disposed at an exterior surface of the central region; and a further set of one or more metallizations formed in the folded substrate electrically connect the first set of one or more contacts and the fourth set of one or more contacts.
Aspect 18. An electronic device, comprising: a multichip module including a folded substrate comprising a central region having a first set of one or more contacts at an inner surface of a first side portion of the central region and a second set of one or more contacts at an inner surface of a second side portion of the central region, at least a first flap adjacent to the first side portion of the central region and a second flap adjacent the second side portion of the central region, the first flap having a third set of one or more contacts at at an inner surface of the first flap, and the second flap having a fourth set of one or more contacts at at an inner surface of the second flap, the first flap being folded at a first bend line to place the third set of one or more contacts at in electrical contact with the first set of one or more contacts, the second flap being folded at a second bend line to place the fourth set of one or more contacts at in electrical contact with the second set of one or more contacts; a first integrated circuit package electrically connected to a fifth set of one or more contacts at an interior surface of the central region, the first integrated circuit package being disposed in an open region formed between edges of the first flap and the second flap; and a first set of one or more metallizations formed in the folded substrate to electrically connect two or more of the first set of one or more contacts, the second set of one or more contacts, the third set of one or more contacts, the fourth set of one or more contacts, and fifth set of one or more contacts with one another.
Aspect 19. The electronic device of aspect 18, further comprising: a second integrated circuit package electrically connected to a sixth set of one or more contacts disposed at an exterior surface of the first flap and connected to a seventh set of one or more contacts at an exterior surface of the second flap.
Aspect 20. The electronic device of aspect 19, further comprising: a second set one or more metallizations formed in the folded substrate to electrically connect the fifth set of one or more contacts and the sixth set of one or more contacts with at least one of the first set of one or more contacts, the second set of one or more contacts, the third set of one or more contacts, the fourth set of one or more contacts with one another.
Aspect 21. The electronic device of aspect 20, further comprising: a non-conductive layer of a thermal interface material disposed between an exterior surface of the first integrated circuit package and the interior surface of the second integrated circuit package.
Aspect 22. The electronic device of any of aspects 18 to 21, wherein: the first integrated circuit package comprises dynamic random access memory (DRAM) physical interface.
Aspect 23. The electronic device of any of aspects 21 to 22, wherein: the second integrated circuit package comprises a dynamic random access memory (DRAM).
Aspect 24. The electronic device of any of aspects 18 to 23, further comprising: a seventh set of one or more contacts at an exterior surface of the central region configured for connecting the multichip module to a further substrate.
Aspect 25. The electronic device of any of aspects 18 to 24, wherein the electronic device comprises at least one of: a music player; a video player; an entertainment unit; a navigation device; a communications device; a mobile device; a mobile phone; a smartphone; a personal digital assistant; a fixed location terminal; a tablet computer, a computer; a wearable device; a laptop computer; a server; an internet of things (IoT) device; or a device in an automotive vehicle.
Aspect 26. A multichip module, comprising: a folded substrate comprising a central region having a first set of one or more contacts at an inner surface of a first side portion of the central region and a second set of one or more contacts at an inner surface of a second side portion of the central region, at least a first flap adjacent to the first side portion of the central region and a second flap adjacent the second side portion of the central region, the first flap having a third set of one or more contacts at an inner surface of the first flap, and the second flap having a fourth set of one or more contacts at an inner surface of the second flap, the first flap being folded at a first bend line to place the third set of one or more contacts in electrical contact with the first set of one or more contacts, the second flap being folded at a second bend line to place the fourth set of one or more contacts in electrical contact with the second set of one or more contacts; a first integrated circuit package electrically connected to a fifth set of one or more contacts at an interior surface of the central region, the first integrated circuit package being disposed in an open region formed between edges of the first flap and the second flap; and a first set of one or more metallizations formed in the folded substrate to electrically connect two or more of the first set of one or more contacts, the second set of one or more contacts, the third set of one or more contacts, the fourth set of one or more contacts, and fifth set of one or more contacts with one another.
Aspect 27. The multichip module of aspect 26, further comprising: a second integrated circuit package electrically connected to a sixth set of one or more contacts disposed at an exterior surface of the first flap and connected to a seventh set of one or more contacts at an exterior surface of the second flap.
Aspect 28. The multichip module of aspect 27, further comprising: a second set one or more metallizations formed in the folded substrate to electrically connect the fifth set of one or more contacts and the sixth set of one or more contacts with at least one of the first set of one or more contacts, the second set of one or more contacts, the third set of one or more contacts, the fourth set of one or more contacts with one another.
Aspect 29. The multichip module of aspect 28, further comprising: a non-conductive layer of a thermal interface material disposed between an exterior surface of the first integrated circuit package and the interior surface of the second integrated circuit package.
Aspect 30. The multichip module of any of aspects 26 to 29, wherein: the first integrated circuit package comprises dynamic random access memory (DRAM) physical interface.
Aspect 31. The multichip module of any of aspects 27 to 30, wherein: the second integrated circuit package comprises a dynamic random access memory (DRAM).
Aspect 32. The multichip module of any of aspects 26 to 31, further comprising: a seventh set of one or more contacts at an exterior surface of the central region configured for connecting the multichip module to a further substrate.
Aspect 33. A method of fabricating a multichip module, comprising: forming a folded substrate having a central region and at least a first flap and a second flap disposed at opposite sides of the central region, the first flap being folded at a first bend line to overlie at least a first portion of the central region of the folded substrate, the second flap being folded at a second bend line to overlie a second portion of the central region; electrically connecting a first integrated circuit package electrically to a first set of one or more contacts disposed at an interior surface of the central region of the folded substrate, an interior surface of the first flap overlying at least a portion of the first integrated circuit package, and an interior surface of the second flap overlying at least a further portion of the first integrated circuit package; electrically connecting a second integrated circuit package to a second set of one or more contacts at an outer surface of the first flap; electrically connecting a third integrated circuit package to a third set of one or more contacts at an outer surface of the second flap; and forming one or more metallizations in the folded substrate to electrically connect the first set of one or more contacts at the interior surface of the central region with the second set of one or more contacts at the outer surface of the first flap, the one or more metallizations further electrically connect the first set of one or more contacts at the interior surface of the central region with the third set of one or more contacts at the outer surface of the second flap.
Aspect 34. A method of fabricating a multichip module, comprising: forming a folded substrate having a central region having a first set of one or more contacts at an inner surface of a first side portion of the central region and a second set of one or more contacts at an inner surface of a second side portion of the central region, at least a first flap adjacent to the first side portion of the central region and a second flap adjacent the second side portion of the central region, the first flap having a third set of one or more contacts at an inner surface of the first flap, and the second flap having a fourth set of one or more contacts at an inner surface of the second flap, the first flap being folded at a first bend line to place the third set of one or more contacts in electrical contact with the first set of one or more contacts, the second flap being folded at a second bend line to place the fourth set of one or more contacts in electrical contact with the second set of one or more contacts; electrically connecting a first integrated circuit package to a fifth set of one or more contacts at an interior surface of the central region, the first integrated circuit package being disposed in an open region formed between edges of the first flap and the second flap; and forming a first set of one or more metallizations in the folded substrate to electrically connect two or more of the first set of one or more contacts, the second set of one or more contacts, the third set of one or more contacts, the fourth set of one or more contacts, and fifth set of one or more contacts with one another.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on the bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a patterned metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more patterned metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect(s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An electronic device, comprising:
a multichip module comprising
a folded substrate having a central region and at least a first flap and a second flap disposed at opposite sides of the central region, the first flap being folded at a first bend line to overlie at least a first portion of the central region of the folded substrate, the second flap being folded at a second bend line to overlie a second portion of the central region;
a first integrated circuit package electrically connected to a first set of one or more contacts disposed at an interior surface of the central region of the folded substrate, an interior surface of the first flap overlying at least a portion of the first integrated circuit package, and an interior surface of the second flap overlying at least a further portion of the first integrated circuit package;
a second integrated circuit package electrically connected to a second set of one or more contacts at an outer surface of the first flap;
a third integrated circuit package electrically connected to a third set of one or more contacts at an outer surface of the second flap; and
one or more metallizations formed in the folded substrate to electrically connect the first set of one or more contacts at the interior surface of the central region with the second set of one or more contacts at the outer surface of the first flap, the one or more metallizations further electrically connect the first set of one or more contacts at the interior surface of the central region with the third set of one or more contacts at the outer surface of the second flap.

2. The electronic device of claim 1, further comprising:
a non-conductive layer of a thermal interface material disposed between an exterior surface of the first integrated circuit package and the interior surface of the first flap and between the exterior surface of the first integrated circuit package and the interior surface of the second flap.

3. The electronic device of claim 1, wherein:
the second integrated circuit package and the third integrated circuit package each comprise dynamic random access memory (DRAM); and
the first integrated circuit package comprises a DRAM physical interface (PHYs).

4. The electronic device of claim 2, further comprising:
a third flap folded at a third bend line to overlie at least a third portion of the central region of the folded substrate between the first flap and the second flap;
a fourth integrated circuit package electrically connected to a fourth set of one or more contacts at an exterior surface of the third flap; and
wherein the one or more metallizations further electrically connect the fourth set of one or more contacts with the first set of one or more contacts.

5. The electronic device of claim 3, wherein:
the second integrated circuit package, the third integrated circuit package, and fourth integrated circuit package each comprise dynamic random access memory (DRAM); and
the first integrated circuit package comprises a DRAM physical interface (PHYs).

6. The electronic device of claim 1, further comprising:
a third flap folded at a third bend line to underlie at least a portion of the central region of the folded substrate;
a fourth integrated circuit package electrically connected to a fourth set of one or more contacts at an exterior surface of the third flap; and
wherein the one or more metallizations electrically connect the fourth set of one or more contacts with the first set of one or more contacts.

7. The electronic device of claim 5, wherein:
the second integrated circuit package, the third integrated circuit package, and fourth integrated circuit package each comprise dynamic random access memory (DRAM); and
the first integrated circuit package comprises a DRAM physical interface (PHYs).

8. The electronic device of claim 1, further comprising:
a fourth set of one or more contacts disposed at an exterior surface of the central region; and
a further set of one or more metallizations formed in the folded substrate electrically connect the first set of one or more contacts and the fourth set of one or more contacts.

9. The electronic device of claim 1, wherein the electronic device comprises at least one of:
a music player;
a video player;
an entertainment unit;
a navigation device;
a communications device;
a mobile device;
a mobile phone;
a smartphone;
a personal digital assistant;
a fixed location terminal;
a tablet computer, a computer;
a wearable device;
a laptop computer;
a server;
an internet of things (IoT) device; or
a device in an automotive vehicle.

10. A multichip module, comprising
a folded substrate having a central region and at least a first flap and a second flap disposed at opposite sides of the central region, the first flap being folded at a first bend line to overlie at least a first portion of the central region of the folded substrate, the second flap being folded at a second bend line to overlie a second portion of the central region;
a first integrated circuit package electrically connected to a first set of one or more contacts disposed at an interior surface of the central region of the folded substrate, an interior surface of the first flap overlying at least a portion of the first integrated circuit package, and an interior surface of the second flap overlying at least a further portion of the first integrated circuit package;
a second integrated circuit package electrically connected to a second set of one or more contacts at an outer surface of the first flap;
a third integrated circuit package electrically connected to a third set of one or more contacts at an outer surface of the second flap; and
one or more metallizations formed in the folded substrate to electrically connect the first set of one or more contacts at the interior surface of the central region with the second set of one or more contacts at the outer surface of the first flap, the one or more metallizations further electrically connect the first set of one or more contacts at the interior surface of the central region with the third set of one or more contacts at the outer surface of the second flap.

11. The multichip module of claim 10, further comprising:
a non-conductive layer of a thermal interface material disposed between an exterior surface of the first integrated circuit package and the interior surface of the first flap and between the exterior surface of the first integrated circuit package and the interior surface of the second flap.

12. The multichip module of claim 10, wherein:
the second integrated circuit package and the third integrated circuit package each comprise dynamic random access memory (DRAM); and
the first integrated circuit package comprises a DRAM physical interface (PHYs).

13. The multichip module of claim 12, further comprising:
a third flap folded at a third bend line to overlie at least a third portion of the central region of the folded substrate between the first flap and the second flap;
a fourth integrated circuit package electrically connected to a fourth set of one or more contacts at an exterior surface of the third flap; and
wherein the one or more metallizations further electrically connect the fourth set of one or more contacts with the first set of one or more contacts.

14. The multichip module of claim 13, wherein:
the second integrated circuit package, the third integrated circuit package, and fourth integrated circuit package each comprise dynamic random access memory (DRAM); and
the first integrated circuit package comprises a DRAM physical interface (PHYs).

15. The multichip module of claim 10, further comprising:
a third flap folded at a third bend line to underlie at least a portion of the central region of the folded substrate;
a fourth integrated circuit package electrically connected to a fourth set of one or more contacts at an exterior surface of the third flap; and
wherein the one or more metallizations electrically connect the fourth set of one or more contacts with the first set of one or more contacts.

16. The multichip module of claim 15, wherein:
the second integrated circuit package, the third integrated circuit package, and fourth integrated circuit package each comprise dynamic random access memory (DRAM); and
the first integrated circuit package comprises a DRAM physical interface (PHYs).

17. The multichip module of claim 10, further comprising:
a fourth set of one or more contacts disposed at an exterior surface of the central region; and
a further set of one or more metallizations formed in the folded substrate electrically connect the first set of one or more contacts and the fourth set of one or more contacts.

18. An electronic device, comprising:
a multichip module including
a folded substrate comprising
a central region having a first set of one or more contacts at an inner surface of a first side portion of the central region and a second set of one or more contacts at an inner surface of a second side portion of the central region,
at least a first flap adjacent to the first side portion of the central region and a second flap adjacent the second side portion of the central region, the first flap having a third set of one or more contacts at at an inner surface of the first flap, and the second flap having a fourth set of one or more contacts at at an inner surface of the second flap,
the first flap being folded at a first bend line to place the third set of one or more contacts at in electrical contact with the first set of one or more contacts,
the second flap being folded at a second bend line to place the fourth set of one or more contacts at in electrical contact with the second set of one or more contacts;
a first integrated circuit package electrically connected to a fifth set of one or more contacts at an interior surface of the central region, the first integrated circuit package being disposed in an open region formed between edges of the first flap and the second flap; and
a first set of one or more metallizations formed in the folded substrate to electrically connect two or more of the first set of one or more contacts, the second set of one or more contacts, the third set of one or more contacts, the fourth set of one or more contacts, and fifth set of one or more contacts with one another.

19. The electronic device of claim 18, further comprising:
a second integrated circuit package electrically connected to a sixth set of one or more contacts disposed at an exterior surface of the first flap and connected to a seventh set of one or more contacts at an exterior surface of the second flap.

20. The electronic device of claim 19, further comprising:
a second set one or more metallizations formed in the folded substrate to electrically connect the fifth set of one or more contacts and the sixth set of one or more contacts with at least one of the first set of one or more contacts, the second set of one or more contacts, the third set of one or more contacts, the fourth set of one or more contacts with one another.
